(19) United States
(12) Patent Application Publication
(10) Pub. No.: US 2012/0062284 A1
(43) Pub. Date: Mar. 15, 2012

(54) LOW-VOLTAGE DATA RETENTION CIRCUIT AND METHOD

(76) Inventors: WANG YING, Suzhou (CN); Hwi-Taek Chung, Yongin-si (KR)

(21) Appl. No.: 13/231,431

(22) Filed: Sep. 13, 2011

(30) Foreign Application Priority Data
Sep. 14, 2010 (CN) 201010282658.8
Jul. 22, 2011 (KR) 2011-0073037

(51) Int. Cl. H03L 7/00

(52) U.S. Cl. 327/143

(57) ABSTRACT

A low-voltage data retention circuit and method are provided. The circuit includes a reference voltage generating circuit generating a stable reference voltage, a voltage detecting circuit detecting a voltage of a power supply, a comparing circuit for comparing the detected voltage and the reference voltage, wherein when the detected voltage of the power supply is lower than the reference voltage, the comparing circuit generating a turn-off signal to turn off power consumption modules of an IC chip.

### CROSS-REFERENCE TO RELATED APPLICATIONS

This application claims the benefit of Korean Patent Application No. 10-2011-0073037, filed on Jul. 22, 2011, in the Korean Intellectual Property Office, and Chinese Patent Application No. 201010282658.8, filed on Sep. 14, 2010, in the Chinese Patent Office, the disclosures of which are incorporated by reference herein in their entirety.

### BACKGROUND

1. Technical Field

The embodiments of the present inventive concept relate to a low-voltage data retention circuit and method which can efficiently protect data in the chip.

2. Discussion of Related Art

Integrated circuit (IC) chips are widely used for storing data. If power supply is cut off or a voltage supplied from a power supply becomes lower than a voltage required for operating an IC chip, data in the IC chip is lost.

FIG. 1 is a power supplying system according to a related art. As illustrated in FIG. 1, VDD is a voltage applied to an IC chip, Cpower is a capacitor for stabilizing the operation voltage of the IC chip (hereinafter also referred to as a “stabilizing capacitor”), and nRESET is an external reset signal of the IC chip.

The circuit illustrated in FIG. 1 can accomplish temporary data retention. When the IC chip is powered on, a program can operate normally. Data is set in a storage as a certain value to indicate a process of the program. When the external power supply is suddenly cut off, the voltage VDD of the IC chip can be maintained for a predetermined time period because the capacitor Cpower can accumulate electric charges. If the voltage VDD is maintained to be higher than a predetermined voltage, the data in the chip can be retained, and the chip can operate normally once the external power supply is resumed. At this time, the set data value can be retained as the value before power-off.

According to the related art, data retention of the IC chip relies on charge accumulating capability of the capacitor Cpower. However, as the manufacturing process is advanced in the field of the deep submicron, the operation voltage of a chip circuit becomes lower and lower, and some logical circuits can operate at the voltage lower than 1V. When power supply is cut off, the chip consumes large power under the normal operation mode, so that the capacitor Cpower is sharply discharged. According to an electric charge-voltage relation applied to a capacitor, i.e., C×^{Δ}V=I×^{Δ}t, the voltage of the capacitor Cpower instantaneously becomes zero. When the chip is powered on again, the chip is reset and cannot retain the previous data.

### SUMMARY

Exemplary embodiments of the present inventive concept provide a low-voltage data retention circuit and method for an IC chip, which determine whether to turn off the power-consumption modules in the IC chip by comparing a voltage of a power supply and a reference voltage when the IC chip is powered off and decrease the discharging speed of a stabilizing capacitor, thus efficiently protecting data in the IC chip.

According to an embodiment of the present inventive concept, a low-voltage data retention circuit is provided in an integrated circuit (IC) chip. The data retention circuit includes a reference voltage generating circuit generating a stable reference voltage, a voltage detecting circuit detecting a voltage of a power supply, and a comparing circuit comparing the detected voltage and the reference voltage. When the detected voltage is lower than the reference voltage, the comparing circuit generates a turn-off signal to turn off power consumption modules in the IC chip.

The reference voltage generating circuit has a self-adjusting function adjusting the reference voltage to a desired value by detecting a variation of the reference voltage with a process change.

The voltage detecting circuit and the comparing circuit have a low power consumption characteristic.

The voltage detecting circuit divides the voltage of the power supply through resistors connected to each other in series, diodes, or diode-connected transistors connected to each other to detect the voltage of the power supply.

The reference voltage generating circuit having self-adjusting function includes a 1^{st} NOT gate, a 2^{nd} NOT gate, a 1^{st} AND gate, a 2^{nd} AND gate, a 3^{rd} AND gate, a 1^{st} resistor, a 2^{nd} resistor, a 3^{rd} resistor, a 1^{st} N channel transistor, a 2^{nd} N channel transistor and a 3^{rd} N channel transistor, wherein an input end of the 1^{st} NOT gate receives a 2^{nd} self-adjusting input signal, an input end of the 2^{nd} NOT gate receives a 1^{st} self-adjusting input signal, a 1^{st} input end of the 1^{st} AND gate receives the 2^{nd} self-adjusting input signal, a 2^{nd} input end of the 1^{st} AND gate is connected to a output end of the 2^{nd} NOT gate, a 1^{st} input end of the 2^{nd} AND gate is connected to the output end of the 2^{nd} NOT gate, a 2^{nd} input end of the 2^{nd} AND gate is connected to the output end of the 1^{st} NOT gate, a 1^{st} input end of the 3^{rd} AND gate is connected to the output end of the 1^{st} NOT gate, a 2^{nd} input end of the 3^{rd} AND gate receives the 1^{st} self-adjusting input signal, a drain of the 1^{st} N channel transistor is connected to a 2^{nd} end of the 1^{st} resistor, a gate of the 1^{st} N channel transistor is connected to the output end of the 3^{rd} AND gate, a source of the 1^{st} N channel transistor is connected to ground, a drain of the 2^{nd} N channel transistor is connected to a 2^{nd} end of the 2^{nd} resistor, a gate of the 2^{nd} N channel transistor is connected to the output end of the 2^{nd} AND gate, a source of the 2^{nd} N channel transistor is connected to the ground, a drain of the 3^{rd} N channel transistor is connected to a 2^{nd} end of the 3^{rd} resistor, a gate of the 3^{rd} N channel transistor is connected to the output end of the 1^{st} AND gate, a source of the 3^{rd} N channel transistor is connected to the ground, a 1^{st} end of the 1^{st} resistor is connected to the ground, the 2^{nd} end of the 1^{st} resistor is connected to a 1^{st} end of the 2^{nd} resistor, and the 2^{nd} end of the 2^{nd} resistor is connected to a 1^{st} end of the 3^{rd} resistor.

The 1^{st} self-adjusting input signal and the 2^{nd} self-adjusting signal are digital signals.

The comparing circuit includes a 2-stage inverting circuit to increase driving capability of the turn-off signal.

According to an embodiment of the present inventive concept, a low-voltage data retention method includes generating a reference voltage, detecting a voltage of a power supply, comparing the reference voltage and the detected voltage, and generating a turn-off signal to turn off power consumption modules in an IC chip when the detected voltage is lower than the reference voltage.

According to an embodiment, there is provided a data retention circuit for an integrated circuit (IC) chip, comprising a reference voltage generating circuit configured to generate a reference voltage and a bias voltage based on a voltage of a power supply, a voltage detecting circuit configured to divide the voltage of the power supply to output a divided voltage, a comparing circuit configured to receive the reference voltage, the bias voltage, and the divided voltage and to compare the reference voltage and the divided voltage with each other to determine whether to turn off a power consumption module in the IC chip, and a main block configured to supply a turn-off signal to the voltage detecting circuit and the comparing circuit to turn off the voltage detecting circuit and the comparing circuit when the IC chip is in a stop mode and configured to supply a signal for adjusting a bias resistor of the reference voltage generating circuit to the reference voltage generating circuit.

### BRIEF DESCRIPTION OF THE DRAWINGS

The embodiments of the present inventive step will become apparent and more readily understood from the following detailed description, taken in conjunction with the accompanying drawings, in which:

FIG. 1 is a power supplying system according to a related art;

FIG. 2 is a block diagram of a low-voltage data retention circuit in an IC chip according to an embodiment of the present inventive concept;

FIG. 3 is a circuit diagram of the reference voltage generating circuit illustrated in FIG. 2 according to an embodiment of the present inventive concept;

FIG. 4 is a circuit diagram of the voltage detecting circuit and the comparing circuit illustrated in FIG. 2 according to an embodiment of the present inventive concept;

FIG. 5 is a circuit diagram of the comparing circuit illustrated in FIG. 4 according to an embodiment of the present inventive concept;

FIG. 6 is a flowchart of a low-voltage data retention method according to an embodiment of the present inventive concept;

FIG. 7 illustrates waveforms of various voltages in a circuit adopting data retention according to an embodiment of the present inventive concept;

FIG. 8 is a flowchart of testing data retention in a memory unit of a chip; and

FIG. 9 illustrates voltage testing results based on a related art and an embodiment of the present inventive concept.

### DETAILED DESCRIPTION OF THE EMBODIMENTS

Exemplary embodiments of the present inventive concept will be described in greater detail with reference to the accompanying drawings, wherein the same reference numerals may refer to the same or substantially the same elements throughout the specification and the drawings.

FIG. 2 is a block diagram of a low-voltage data retention circuit according to an embodiment of the present inventive concept. The circuit includes a reference voltage generating circuit, a voltage detecting circuit, and a comparing circuit.

A main block supplies a disable signal to the voltage detecting circuit and the comparing circuit to turn off the voltage detecting circuit and the comparing circuit, and supplies a signal for adjusting a bias resistor to the reference voltage generating circuit.

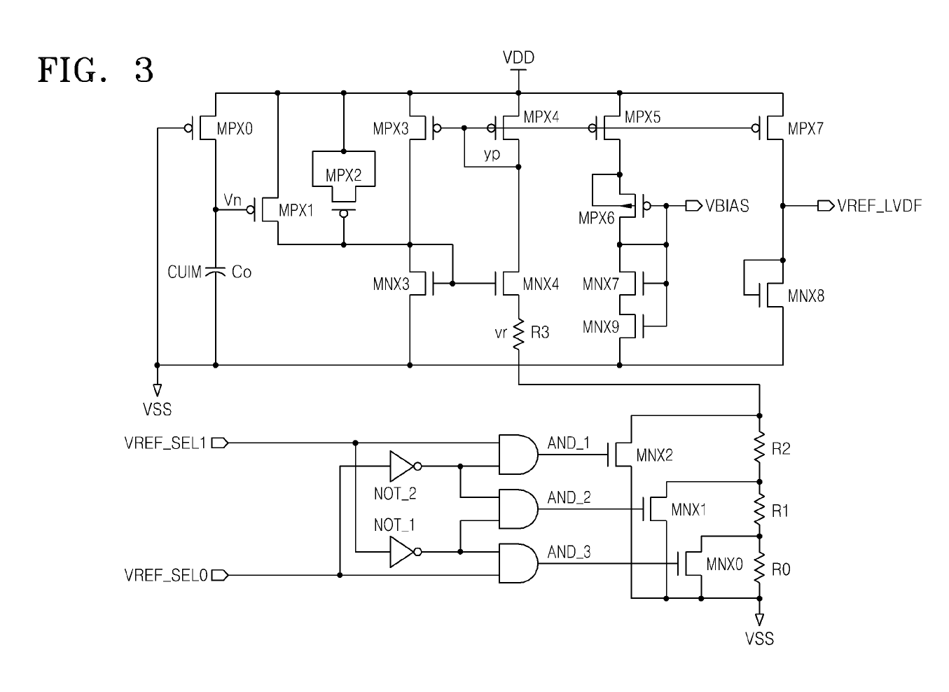

The reference voltage generating circuit generates a reference voltage and a bias voltage, and supplies the reference voltage and the bias voltage to the comparing circuit. The structure and the operation principle of the reference voltage generating circuit will be described in greater detail by referring to FIG. 3.

The voltage detecting circuit divides the voltage of the power supply and supplies the divided voltage to the comparing circuit.

The comparing circuit receives the reference voltage and the bias voltage generated by the reference voltage generating circuit and the divided voltage by the voltage detecting circuit, and compares the divided voltage and the reference voltage to determine whether to turn off the power consumption modules in the chip.

FIG. 3 is a circuit diagram of the reference voltage generating circuit illustrated in FIG. 2 according to an embodiment of the present inventive concept. Hereinafter, the reference voltage generating circuit will be described in detail with reference to FIG. 3. In the following description, a P channel transistor and an N channel transistor are referred as a P transistor and an N transistor for convenience of description.

A start-up circuit of the reference voltage generating circuit comprises a 1^{st} P transistor MPX0, a 2^{nd} P transistor MPX1, and a capacitor C0. A gate of the 1^{st} P transistor MPX0 is connected to ground, a source of the 1^{st} P transistor MPX0 is connected to a power supply VDD, and a drain of the 1^{st} P transistor MPX0 is connected to a gate of the 2^{nd} P transistor MPX1. The gate of the 2^{nd} P transistor MPX1 is connected to the drain of the 1^{st} P transistor MPX0, a source of the 2^{nd} P transistor MPX1 is connected to the power supply VDD, and a drain of the 2^{nd} P transistor MPX1 is connected to a drain of a 4^{th} N transistor MNX3. A first end of the capacitor C0 is connected to the drain of the 1^{st} P transistor MPX0, and a second end of the capacitor C0 is connected to the ground. The gate voltage of the 2^{nd} P transistor MPX1 is referred to as Vn.

When the power supply is powered on, an initial voltage value of the capacitor C0 is 0, and the 2^{nd} P transistor MPX1 turns on to operate, so that the voltage Vn increases. The power supply charges the capacitor through the 1^{st} P transistor MPX0. When the voltage between the gate and the source of the 1^{st} P transistor MPX0 is larger than a threshold voltage of the 1^{st} P transistor, the voltage of the gate of 2^{nd} P transistor MPX1 varies with the voltage of the power supply, so that the 2^{nd} P transistor MPX1 turns off, and the start-up of the circuit is completed.

A 4^{th} p transistor MPX3, a 5^{th} P transistor MPX4, a 6^{th} P transistor MPX5, and an 8^{th} transistor MPX7 form a current mirror circuit. A gate of the 4^{th} P transistor MPX3 is connected to a gate of the 5^{th} P transistor MPX4, a source of the 4^{th} P transistor MPX3 is connected to the power supply VDD, and a drain of the 4^{th} P transistor MPX3 is connected to a drain of the 4^{th} N transistor MNX3. A gate and a drain of the 5^{th} P transistor MPX4 are connected to each other, a source of the 5^{th} P transistor MPX4 is connected to the power supply VDD, and the drain of the 5^{th} P transistor MPX4 is connected to a drain of a 5^{th} N transistor MNX4. A gate of the 6^{th} P transistor MPX5 is connected to a gate of the 8^{th} P transistor MPX7 and the gate of the 5^{th} P transistor MPX4, a source of the 6^{th} P transistor MPX5 is connected to the power supply VDD, and a drain of the 6^{th} P transistor MPX5 is connected to a source of the 7^{th} P transistor MPX6. A gate of the 8^{th} P transistor MPX7 is connected to the gate of the 6^{th} P transistor MPX5, a source of the 8^{th} P transistor MPX7 is connected to the power supply VDD, and a drain of the 8^{th} P transistor MPX7 is connected to a drain of a 9^{th} N transistor MNX8. A voltage of the drain of the 8^{th} P transistor MPX7 is referred to as VREF_LVDF, which is output to the voltage detecting circuit and the comparing circuit. The gate and the drain of the 9^{th} transistor MNX8 are connected to each other, and the source of the 9^{th} transistor MNX8 is connected to the ground.

The gate and the drain of the 4^{th} N transistor MNX3 are connected to each other, the gate of the 4^{th} N transistor MNX3 is connected to the gate of the 5^{th} N transistor MNX4, the drain of the 4^{th} N transistor MNX3 is connected to the drain of the 4^{th} P transistor MPX3, and the source of the 4^{th} N transistor MNX3 is connected to the ground. The gate of the 5^{th} N transistor MNX4 is connected to the gate of the 4^{th} N transistor MNX3, the drain of the 5^{th} N transistor MNX4 is connected to the drain of the 5^{th} P transistor MPX4, and the source of the 5^{th} N transistor MNX4 is connected to an end of a 4^{th} resistor R3.

A source of the 7^{th} P transistor MPX6 is connected to the drain of the 6^{th} P transistor MPX5, the gate of the 7^{th} P transistor MPX6 outputs a bias voltage VBIAS, and the drain and the gate of the 7^{th} P transistor MPX6 are connected to each other. A gate of the 8^{th} N transistor MNX7 is connected to the gate of the 7^{th} P transistor MPX6, the drain of the 8^{th} N transistor MNX7 is connected to the drain of the 7^{th} P transistor MPX6, and the source of the 8^{th} N transistor MNX7 is connected to the drain of the 10^{th} N transistor MNX9. The gate of the 10^{th} N transistor MNX9 is connected to the gate of the 8^{th} N transistor MNX7, the drain of the 10^{th} N transistor MNX9 is connected to the source of the 8^{th} N transistor MNX7, and the source of the 10^{th} N transistor MNX9 is connected to the ground.

The self-adjustment of the reference voltage is implemented by NOT gates NOT_1 and NOT_2, AND gates AND_1, AND_2, and AND_3, a 1^{st} resistor R0, a 2^{nd} resistor R1, and a 3^{rd} resistor R2, and a 1^{st} N transistor MNX0, a 2^{nd} N transistor MNX1, and a 3^{rd} N transistor MNX2. The connections of the above elements are described below. An input end of the NOT gate NOT_1 receives a signal VERF_SEL1, an input end of the NOT gate NOT_2 receives a signal VREF_SEL0. A first input end of the AND gate AND_1 receives the signal VREF_SEL1, and a second input end of the AND gate AND_1 is connected to an output end of the NOT gate NOT_2. A first input end of the AND gate AND_2 is connected to the output end of the NOT gate NOT_1, and a second input end of the AND gate AND_2 is connected to the output end of the NOT gate NOT_2. A first input end of the AND gate AND_3 is connected to the output end of the NOT gate NOT_1, and a second input end of the AND gate AND_3 receives the signal VREF_SEL0. A drain of the 1^{st} N transistor MNX0 is connected to a second end of the 1^{st} resistor R0, a gate of the 1^{st} N transistor MNX0 is connected to the output end of the AND gate AND_3, and the source of the 1^{st} N transistor MNX0 is connected to the ground. The drain of the 2^{nd} N transistor MNX1 is connected to a second end of the 2^{nd} resistor R1, the gate of the 2^{nd} N transistor MNX1 is connected to the output end of the AND gate AND_2, and the source of the 2^{nd} N transistor MNX1 is connected to the ground. The drain of the 3^{rd} N transistor MNX2 is connected to a second end of the 3^{rd} resistor R2, the gate of the 3^{rd} N transistor MNX2 is connected to the output end of the AND gate AND_1, and the source of the 3^{rd} N transistor MNX2 is connected to the ground. A first end of the 1^{st} resistor R0 is connected to the ground, a first end of the 2^{nd} resistor R1 is connected to the second end of the 1^{st} resistor R0, and a first end of the 3^{rd} resistor R2 is connected to the second end of the 2^{nd} resistor R1. A second end of the 4^{th} resistor R3 is connected to the 5^{th} N transistor MNX4, and a first end of the 4^{th} resistor R3 is connected to the 3^{rd} resistor R2.

I_{MPX3}, I_{MPX4}, I_{MPX5}, and I_{MPX7} respectively indicate currents output from the drains of the transistors MPX3, MPX4, MPX5, and MPX7. WP3/LP3, WP4/LP4, WP5/LP5, and WP7/LP7 respectively indicate width-length ratios of gate channels of the transistors MPX3, MPX4, MPX5, and MPX7.

I_{MPX3}, I_{MPX4}, I_{MPX5}, and I_{MPX7} have the following relationships:

I_{MPX3}/I_{MPX4}=(WP3/LP3)/(WP4/LP4) (1)

I_{MPX5}/I_{MPX4}=(WP5/LP5)/(WP4/LP4) (2)

I_{MPX7}/I_{MPX4}=(WP7/LP7)/(WP4/LP4) (3)

WN3/LN3, WN4/LN4, and WN8/LN8 respectively indicate width-length ratios of gate channels of the transistors MNX3, MNX4, and MNX8. R indicates a bias resistance. A method of setting the bias resistance will be described later.

I_{MNX3}=μCox(WN3/LN3)×(VGS_{MNX3}−VTH)²=I_{MPX3} (4)

I_{MNX4}=μCox(WN4/LN4)×(VGS_{MNX4}−VTH)²=I_{MPX4} (5)

VGS_{MNX3}=VGS_{MNX4}+I_{MNX4}×(R) (6)

I_{MPX7}=μCox(WN8/LN8)×(VREF_{—}LVDF−VTH) (7)

Here, μ indicates an electronic traction ratio, and Cox indicates a gate oxide capacitance.

From equations (1) to (7), the voltage VREF_LVDF is inversely proportional to the bias resistance R.

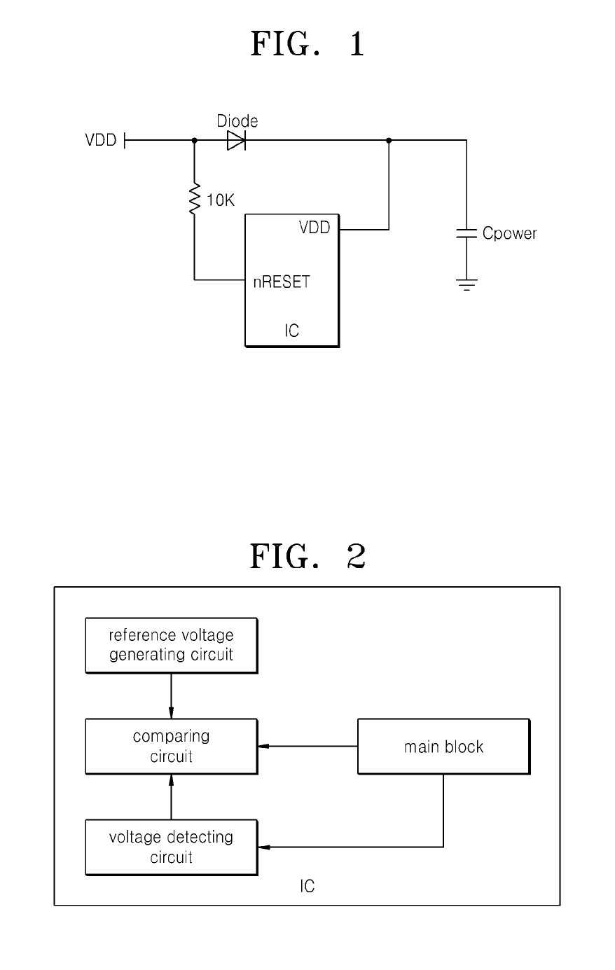

For the reasons associated with the process technology, for example, since a tiny variation in the process conditions occurs overtime, the reference voltage VREF_LVDF of each IC cannot reach the requirements. Thus, when the chip is manufactured, the generated reference voltage is measured, and based on the measured reference voltage, the signals VERF_SEL0 and VREF_SEL1 having appropriate values are supplied by the main block of FIG. 1 while the chip operates to set bias resistance, so that the reference voltage meeting the requirement is generated. The relationship between VREF_SEL0 and VREF_SEL1, and the bias resistance is illustrated as table 1.

TABLE 1
Relationship between VREF_SEL0 and
VREF_SEL1 and bias resistance

| VREF_SEL0 | VREF_SEL1 | Bias resistance |
|---|---|---|
| 0 | 0 | R2 + R3 |
| 0 | 1 | R1 + R2 + R3 |
| 1 | 0 | R3 |
| 1 | 1 | R0 + R1 + R2 + R3 |

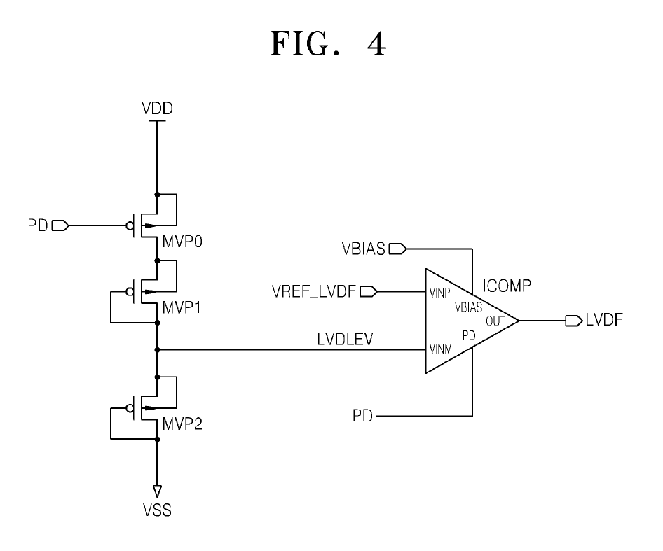

Hereinafter, the voltage detecting circuit and the comparing circuit according to an exemplary embodiment of the present inventive concept are described with reference to the FIG. 4. FIG. 4 is a circuit diagram of the voltage detecting circuit and the comparing circuit illustrated in FIG. 2 according to an embodiment of the present inventive concept.

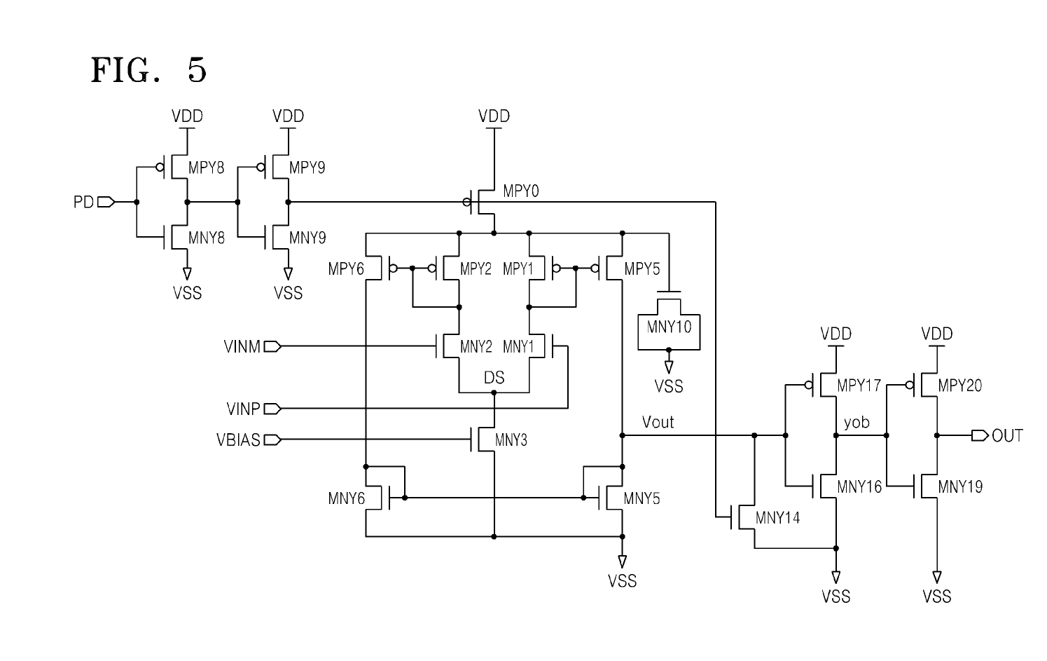

As illustrated in FIG. 4, the gate of a 1^{st} P channel enhancement mode transistor MVP0 receives a turn-off signal PD, the source of the 1^{st} P channel enhancement mode transistor MVP0 is connected to the power supply VDD, and the drain of the 1^{st} P channel enhancement mode transistor MVP0 is connected to the source of a 2^{nd} enhancement mode transistor MVP1, the gate and the drain of the 2^{nd} enhancement mode transistor MVP1 are connected to each other, and the source of the 2^{nd} enhancement mode transistor MVP1 is connected to the drain of the transistor MVP0. The gate and the drain of a 3^{rd} P channel enhancement mode transistor MVP2 are connected to each other, the source of the transistor MVP2 is connected to the drain of the transistor MVP1, and the drain of the transistor MVP2 is connected to the ground. ICOMP is a low power consumption comparator, the detailed structure and operation principle of which will be described with reference to FIG. 5.

The voltage detecting circuit receives the turn-off signal PD. When the chip is in a stop mode, PD is in a high level, and the circuit in the chip can be thus turned off, thereby saving power consumption of the chip. The transistor MVP1 is a switch transistor. When the chip is in the stop mode, PD is in the high level, and the transistor MVP0 is in a turn-off state. When the chip is in a normal operation mode, the transistor MVP0 turns on. The transistors MVP1 and MVP2 are connected to each other in a diode-operation status to function as a voltage-dividing resistor string. To accomplish a low power consumption status, width-length ratios (W/L ratios) of gate channels of the transistors MVP1 and MVP0 are set as relatively small values. A divided voltage LVDLEV is generated by dividing a voltage of the power supply through the transistors MVP1 and MVP2, and is used as an inverse input of the comparing circuit. According to an embodiment, the voltage-dividing resistor string may be also implemented by passive resistors and other elements, such as diodes.

A positive end of the comparing circuit ICOMP receives the reference voltage VREF_LVDF generated by the reference voltage generating circuit, and a negative end of the comparing circuit ICOMP receives the divided voltage LVDLEV. When the comparing circuit detects that the divided voltage LVDLEV is higher than the reference voltage VREF_LVDF, the output LVDF of the comparing circuit is in a low level. When the comparing circuit detects that the divided voltage LVDLEV is lower than the reference voltage VREF_LVDF, the output LVDF of the comparing circuit is in a high level, and all of the power consumption modules in the chip are turned off, so that the discharging speed of the capacitor (for example, the stabilizing capacitor Cpower as shown in FIG. 1) is decreased and the chip is in the low power consumption operation mode.

Hereinafter, the comparing circuit ICOMP of FIG. 4 will be described in greater detail with reference to FIG. 5. FIG. 5 is a circuit diagram of the comparing circuit illustrated in FIG. 4 according to an embodiment of the present inventive concept.

In FIG. 5, transistors MPY8, MNY8, MPY9, and MNY9 form a 1^{st} 2-stage inverting circuit. Transistors MPY6 and MPY2 form a first mirror circuit, the transistors MPY1 and MPY5 form a second mirror circuit, and the transistors MNY6 and MNY5 form a third mirror circuit. Transistors MNY2 and MNY1 form a differential input pair. Transistors MNY14, MPY17, MNY16, MNY19, and MPY20 form a 2^{nd} 2-stage inverting circuit.

In the 1^{st} 2-stage inverting circuit, a source of the 9^{th} P transistor MPY8 is connected to the power supply VDD, the gate of the transistor MPY8 receives the input signal PD, and the drain of the transistor MPY8 is connected to the drain of the 9^{th} N transistor MNY8. The gate of the 9^{th} N transistor MNY8 receives the input signal PD, the drain of the transistor MNY8 is connected to the drain of the 9^{th} P transistor MPY8, and the source of the transistor MNY8 is connected to the ground. The gate of the 10^{th} P transistor MPY9 is connected to the drain of the 9^{th} P transistor MPY8, the source of the transistor MPY9 is connected to the power supply VDD, and the drain of the transistor MPY9 is connected to the drain of the 10^{th} transistor MNY9. The gate of the 10^{th} transistor MNY9 is connected to the drain of the 9^{th} N transistor MNY8, the source of the transistor MNY9 is connected to the ground, and the drain of the transistor MNY9 is connected to the drain of the 10^{th} P transistor MPY9.

In the 1^{st} mirror circuit, the gate of the 7^{th} P transistor MPY6 is connected to the gate of the 3^{rd} P transistor MPY2, the drain of the transistor MPY6 is connected to the source of the 7^{th} N transistor MNY6, and the source of the transistor MPY6 is connected to the drain of the 1^{st} P transistor MPY0. The gate of the 3^{rd} P transistor MPY2 is connected to the gate of the 7^{th} P transistor MPY6, the drain of the transistor MPY2 is connected to the drain of the 3^{rd} N transistor MNY2, the source of the transistor MPY2 is connected to the drain of the 1^{st} P transistor MPY0, and the gate and the drain of the transistor MPY2 are connected to each other. The 3^{rd} P transistor MPY2 is used as an input load.

In the 2^{nd} mirror circuit, the gate of the 2^{nd} P transistor MPY1 is connected to the gate of the 6^{th} P transistor MPY5, the drain of the transistor MPY1 is connected to the drain of the 2^{nd} N transistor MNY1, the source of the transistor MPY1 is connected to the drain of the 1^{st} P transistor MPY0, and the drain and the gate of the transistor MPY1 are connected to each other. The gate of the 6^{th} P transistor MPY5 is connected to the gate of the 2^{nd} P transistor MPY1, the drain of the transistor MPY5 is connected to an input end of the 2-stage inverting circuit (for example, the gates of the transistors MNY16 and MPY17), and the source of the transistor MPY5 is connected to the drain of the 1^{st} P transistor MPY0. The 2^{nd} P transistor MPY1 is used as an input load.

In the 3^{rd} mirror circuit, the gate of the 7^{th} N transistor MNY6 is connected to the gate of the 6^{th} N transistor MNY5, the drain of the transistor MNY6 is connected to the ground, the source of the transistor MNY6 is connected to the drain of the 7^{th} P transistor MPY6, and the source and the gate of the transistor MNY6 are connected to each other. The gate of the 6^{th} N transistor MNY5 is connected to the gate of the 7^{th} N transistor MNY6, the drain of the transistor MNY5 is connected to the ground, and the source of the transistor MNY5 is connected to the drain of the 6^{th} P transistor MPY5.

In the differential input pair, the gate of the 3^{rd} N transistor MNY2 receives an input signal VINM, the drain of the transistor MNY2 is connected to the drain of the 3^{rd} P transistor MPY2, and the source of the transistor MNY2 is connected to the source of the 2^{nd} N transistor MNY1. The gate of the 2^{nd} N transistor MNY1 receives an input signal VINP, the drain of the transistor MNY1 is connected to the drain of the 2^{nd} P transistor MPY1, and the source of the transistor MNY1 is connected to the drain of the 4^{th} N transistor MNY3.

In the 2^{nd} 2-stage inverting circuit, the gate of the 18^{th} P transistor MPY17 and the 17^{th} N transistor MNY16 are connected to each other as an input terminal of the 2^{nd} 2-stage inverting circuit and receive an input signal. The drain of the 21^{th} P transistor MPY20 and the drain of the 20^{th} N transistor MNY19 are connected to each other as an output terminal of the 2^{nd} 2-stage inverting circuit. The gate of the 18^{th} P transistor MPY17 is connected to the gate of the 17^{th} N transistor MNY16, the source of the transistor MPY17 is connected to the power supply VDD, the drain of the transistor MPY17 is connected to the drain of the 17^{th} N transistor MNY16. The gate of the 17^{th} N transistor MNY16 is connected to the drain of the 6^{th} P transistor MPY5, the drain of the transistor MNY16 is connected to the drain of the 18^{th} P transistor MPY17, and the source of the transistor MNY16 is connected to the ground. The gate of the 21^{th} P transistor MPY20 is connected to the gate of the 20^{th} N transistor MNY19, the source of the transistor MPY20 is connected to the power supply VDD, and the drain of the transistor MPY20 is connected to the drain of 20^{th} transistor MNY19. The gate of the 20^{th} N transistor MNY19 is connected to the drain of the 18^{th} P transistor MPY17, the drain of the transistor MNY19 is connected to the drain of the 21^{th} P transistor MPY20, and the source of the transistor MNY19 is connected to the ground. The gate of the 15^{th} N transistor MNY14 is connected to the gate of the 1^{st} P transistor MPY0, the drain of the transistor MNY14 is connected to the gate of the 18^{th} P transistor MPY17, and the source of the transistor MNY14 is connected to the ground.

The transistor MNY3 forms a bias circuit. The gate of the transistor MNY3 receives the bias voltage VBIAS, the drain of the transistor MNY3 is connected to the sources of the transistors MNY1 and MNY2, and the source of the transistor MNY3 is connected to the ground.

In the detecting circuit, when the chip is in the stop mode, for example, PD is in a high level, the comparing circuit can be turned off. The bias-voltage VBIAS of the comparing circuit is supplied by the reference voltage generating circuit illustrated in FIG. 2. When VINP is higher than VINM, the current flowing through the transistor MNY1 is higher than the current flowing through the transistor MNY2, thus the current flowing through the transistor MPY5 is higher than the current flowing through the transistor MPY6. Therefore, the output voltage VOUT is in a high level, and is output through the 2^{nd} 2-stage inverting circuit. When the VINP is lower than the VINM, the output voltage VOUT is in a low level and is output through the 2^{nd} 2-stage inverting circuit.

The comparing circuit includes the 2^{nd} 2-stage inverting circuit to increase the driving capability of the output voltage VOUT. Alternatively, the comparing circuit may operate without the 2^{nd} 2-stage inverting circuit, and the output voltage VOUT can be directly output from the comparing circuit as a comparing result.

With reference to FIG. 4 and FIG. 5, to decrease the power consumption, the width-length ratios of the gate channels of the transistors MVP1 and MVP2 illustrated in FIG. 4 and the transistor MNY3 illustrated in FIG. 5 may be appropriately set. Usually, as the power consumption decreases, time for the data retention increases.

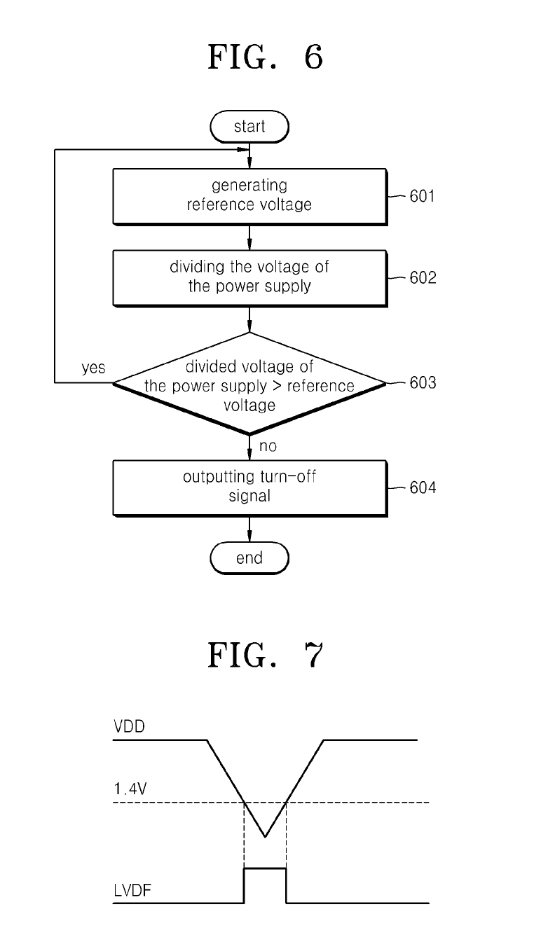

FIG. 6 is a flowchart of a low-voltage data retention method according to an embodiment of the present inventive concept.

The reference voltage is generated by the reference voltage generating circuit at step 610. The voltage of the power supply is divided at step 602. The divided voltage of the power supply and the reference voltage are compared with each other at step 603. If the reference voltage is higher than divided voltage of the power supply, the high level signal for turning off the power consumption modules is output at step 604.

FIG. 7 illustrates waveforms of various voltages in a data retention circuit according to an embodiment of the present inventive concept.

Referring to FIG. 7, the reference voltage is set as 1.4V. The reference voltage circuit as illustrated in FIG. 3 generates 1.4V of the reference voltage as a VINP input of the comparing circuit illustrated in FIG. 5, the voltage-dividing resistor string including the MVP1 and MVP2 as illustrated in FIG. 4 divides a voltage of the power supply as a VINM input of the comparing circuit as illustrated in FIG. 5. When VINM<1.4V, LVDF is in a high level, so that the power consumption modules of the IC chip are turned off.

Compared to the related art, the power consumption of the chip is greatly decreased by using the low voltage protection circuit according to the embodiments of the present inventive concept, so that the data retention is implemented.

TABLE 2

| | | 25° C. | 25° C. | 25° C. | 25° C. | 25° C. | −40° C. | 85° C. |
|---|---|---|---|---|---|---|---|---|
| | | NN | FF | SS | FS | SF | FF | SS |
| Detected | before fine | 1.392 | 1.216 | 1.614 | 1.221 | 1.600 | 1.395 | 1.558 |
| voltage | tuning (V) | | | | | | | |
| | After fine | 1.392 | 1.386 | 1.414 | 1.375 | 1.400 | 1.550 | 1.358 |
| | tuning (V) | | | | | | | |

| | | | | | | | |
|---|---|---|---|---|---|---|---|
| Power consumption | 0.556 | 0.537 | 0.552 | 0.458 | 0.488 | 0.372 | 0.652 |
| (μA) | | | | | | | |

In table 2, the “fine tuning” means that VREF_LVDF is adjusted by using VREF_SEL1 and VREF_SEL0 before the IC chip leaves factory. The “before fine tuning” means the testing results obtained when the IC chip is manufactured, and the “after fine tuning” means the results obtained by adjusting the chip using VREF_SEL1 and VREF_SEL0. “S” indicates that MOS is in a worst condition, “F” indicates that the MOS is in a best condition, and “N” indicates that the MOS is in a normal condition. “SF” indicates that NMOS transistor is in a worst condition and PMOS transistor is in a best condition. “SS”, “SF”, “NN”, “FS”, and “FF” indicate five different process conditions.

Table 2 is an HSPICE simulation result based on a 13 μm process. It can be seen from table 2 that power consumption of the detecting circuit according to an embodiment of the present inventive concept is low with average power consumption of about 0.6 μA. When the voltage of the power supply decreases to a predetermined voltage value, the power consumption modules of the chip are turned off immediately, thereby decreasing the discharging speed of the stabilizing capacitor. As a consequence, the data is retained for a long time. When the chip is powered on, the chip can resume the previous operation.

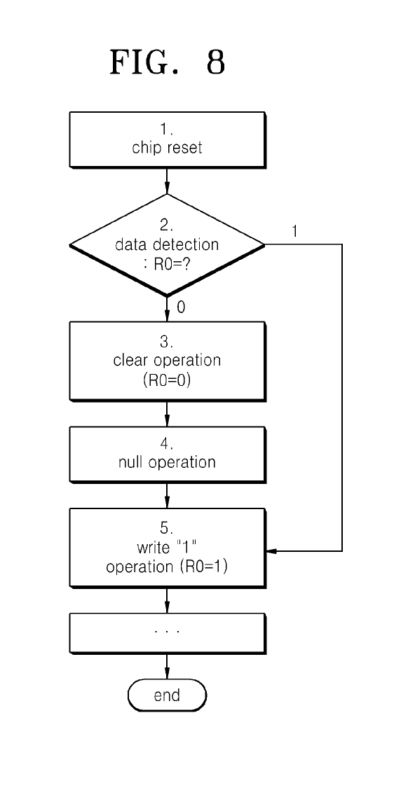

FIG. 8 is a flowchart of testing data retention in a memory unit of a chip according to an embodiment of the present inventive concept. In operation 1, the chip is reset. Operation 1 is performed before the chip operates normally. In operation 2, the value of data stored in the memory unit of the chip is determined. For example, it is determined whether data stored in the memory unit is “1” or “0”. In operation 3, when the data stored in the memory unit is “0”, the memory unit is clear, so that the data stored in the memory unit is “0”. Operation 4 is a null operation to maintain data “0” stored in the memory unit. In operation 5, data “1” is written to the memory unit. For example, data “0” is replaced by data “1”. When operation 5 is completed, the chip is powered off. The data stored in the memory unit is lost after the chip is powered off according to the conventional chip design. For example, data “1” written in operation 5 is changed to data “0”. When the chip is powered on again, if a data retention circuit according to an embodiment of the present inventive concept is not provided in the chip, operations 1, 2, 3, 4, and 5 are sequentially performed. However, if a data retention circuit according to an embodiment of the present inventive concept is provided in the chip, data “1” stored in the memory unit is still retained even after the chip is powered off. When the chip is powered on again, operation 1 and operation 2 are performed, so that the data is determined as “1”, and the process proceeds to operation 5. Then, data test operations after operation 5 are performed by other programs. As such, the storing state of the memory unit is not affected by power off. Testing results for an embodiment of the present inventive concept and the related art based on the above testing operations are illustrated in table 3.

| | Testing phenomenon and result | |
|---|---|---|
| Operation | | Embodiment of the present |
| step | Related art | inventive concept |
| 1^{st} step | Operations | Operations |
| chip powered | 1→2→3→4→5 in | 1→2→3→4→5 in |
| on | FIG. 8 | FIG. 8 |
| 2^{nd} step | The voltage of the | The voltage of the |
| chip powered | capacitor sharply | capacitor sharply |
| off after | decreases to about 400 mV, | decreases to about 1.4 V, |
| operation 5 | then slowly decreases | then slowly decrease |
| in FIG. 8 | | |
| 3^{rd} step | Operations | Operations |
| chip powered | 1→2→3→4→5 in | 1→2→5 in FIG. 8, |
| on after 5 | FIG. 8 | the data stored in |
| minutes | | SRAM is retained |

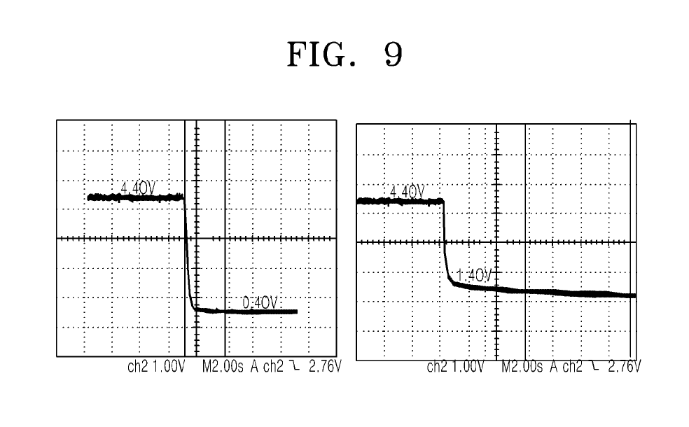

FIG. 9 illustrates voltage testing results based on the related art and an embodiment of the present inventive concept. The left portion illustrates a voltage testing result based on the related art, and the right portion illustrates a voltage testing result based on the embodiment of the present inventive concept. It can be seen from the figure that the power consumption modules are powered off at 1.4V in the chip according to an embodiment of the present inventive concept, so that the stabilizing capacitor is slowly discharged.

While the present inventive concept has been particularly shown and described with reference to exemplary embodiments thereof, so as to illustrate the principle of the present inventive concept, but the present inventive concept is not limited to the shown and described inventive concept. It will be understood by those of ordinary skill in the art that various changes and amendments may be made therein without departing from the spirit and scope of the present inventive concept as defined by the following claims. Thus, it will be understand that these changes, amendments and their equivalents are included in the present inventive concept.

What is claimed is:

1. A data retention circuit on an integrated chip (IC), comprising:
a reference voltage generating circuit configured to generate a reference voltage;
a voltage detecting circuit configured to detect a voltage of a power supply; and
a comparing circuit configured to compare the detected voltage and the reference voltage, wherein when the detected voltage is lower than the reference voltage, the comparing circuit is configured to generate a turn-off signal to turn off power consumption modules of the IC chip.

2. The circuit of claim 1, wherein the reference voltage generating circuit is configured to have a self-adjusting function that adjusts the reference voltage to a desired value by detecting a variation of the reference voltage depending on a process change.

3. The circuit of claim 1, wherein the voltage detecting circuit divides the voltage of the power supply through resistors connected to each other in series or diodes.

4. The circuit of claim 2, wherein the reference voltage generating circuit includes a 1^{st} NOT gate, a 2^{nd} NOT gate, a 1^{st} AND gate, a 2^{nd} AND gate, a 3^{rd} AND gate, a 1^{st} resistor, a 2^{nd} resistor, a 3^{rd} resistor, a 1^{st} N channel transistor, a 2^{nd} N channel transistor, and a 3^{rd} N channel transistor, wherein
an input end of the 1^{st} NOT gate receives a 2^{nd} self-adjusting input signal;
an input end of the 2^{nd} NOT gate receives a 1^{st} self-adjusting input signal;
a 1^{st} input end of the 1^{st} AND gate receives the 2^{nd} self-adjusting input signal, and a 2^{nd} input end of the 1^{st} AND gate is connected to a output end of the 2^{nd} NOT gate;
a 1^{st} input end of the 2^{nd} AND gate is connected to the output end of the 2^{nd} NOT gate, and a 2^{nd} input end of the 2^{nd} AND gate is connected to an output end of the 1^{st} NOT gate;
a 1^{st} input end of the 3^{rd} AND gate is connected to the output end of the 1^{st} NOT gate, and a 2^{nd} input end of the 3^{rd} AND gate receives the 1^{st} self-adjusting input signal;
a drain of the 1^{st} N channel transistor is connected to a 2^{nd} end of the 1^{st} resistor, a gate of the 1^{st} N channel transistor is connected to the output end of the 3^{rd} AND gate, and a source of the 1^{st} N channel transistor is connected to ground;
a drain of the 2^{nd} N channel transistor is connected to a 2^{nd} end of the 2^{nd} resistor, a gate of the 2^{nd} N channel transistor is connected to the output end of the 2^{nd} AND gate, and a source of the 2^{nd} N channel transistor is connected to the ground;
a drain of the 3^{rd} N channel transistor is connected to a 2^{nd} end of the 3^{rd} resistor, a gate of the 3^{rd} N channel transistor is connected to the output end of the 1^{st} AND gate, and a source of the 3^{rd} N channel transistor is connected to the ground;
a 1^{st} end of the 1^{st} resistor is connected to the ground, the 2^{nd} end of the 1^{st} resistor is connected to a 1^{st} end of the 2^{nd} resistor, and the 2^{nd} end of the 2^{nd} resistor is connected to a 1^{st} end of the 3^{rd} resistor.

5. The circuit of claim 4, wherein the 1^{st} self-adjusting input signal and the 2^{nd} self-adjusting signal are digital signals.

6. The circuit of claim 1, wherein the comparing circuit includes a 2-stage inverting circuit configured to increase driving capability of the turn-off signal.

7. A data retention method comprising:
generating a reference voltage;
detecting a voltage of a power supply;
comparing the reference voltage and the detected voltage; and
generating a turn-off signal when the detected voltage is lower than the reference voltage.

8. A data retention circuit for an integrated circuit (IC) chip, comprising:
a reference voltage generating circuit configured to generate a reference voltage and a bias voltage based on a voltage of a power supply;
a voltage detecting circuit configured to divide the voltage of the power supply to output a divided voltage;
a comparing circuit configured to receive the reference voltage, the bias voltage, and the divided voltage and to compare the reference voltage and the divided voltage with each other to determine whether to turn off a power consumption module in the IC chip; and
a main block configured to supply a turn-off signal to the voltage detecting circuit and the comparing circuit to turn off the voltage detecting circuit and the comparing circuit when the IC chip is in a stop mode and configured to supply a signal for adjusting a bias resistor of the reference voltage generating circuit to the reference voltage generating circuit.

9. The data retention circuit of claim 8, wherein the comparing circuit is configured to turn off the power consumption module when the divided voltage is lower than the reference voltage.

10. The data retention circuit of claim 8, wherein the voltage detecting circuit includes a plurality of diode-connected transistors.

11. The data retention circuit of claim 8, wherein the voltage detecting circuit includes a plurality of passive elements connected to each other in series.

12. The data retention circuit of claim 11, wherein the passive elements are resistors.

13. The data retention circuit of claim 8, wherein the reference voltage is inversely proportional to the bias resistor.

14. The data retention circuit of claim 13, wherein the signal for adjusting the bias resistor includes a first self-adjusting input signal and a second self-adjusting input signal.

15. The data retention circuit of claim 14, wherein the reference voltage depends on the first and second self-adjusting input signals.
